(19) United States
(12) Patent Application Publication
(10) Pub. No.: US 2014/0252531 A1
(43) Pub. Date: Sep. 11, 2014

(54) SYSTEMS AND METHODS FOR HARVESTING DISSIPATED HEAT FROM INTEGRATED CIRCUITS (ICS) IN ELECTRONIC DEVICES INTO ELECTRICAL ENERGY FOR PROVIDING POWER FOR THE ELECTRONIC DEVICES

(71) Applicant: QUALCOMM Incorporated, San Diego, CA (US)

(72) Inventors: Babak Aryan, San Diego, CA (US); Senthil Kumar Govindaswamy, San Diego, CA (US); Venkat Rangan, San Diego, CA (US)

(21) Appl. No.: 13/924,687

(22) Filed: Jun. 24, 2013

Related U.S. Application Data
(60) Provisional application No. 61/774,039, filed on Mar. 7, 2013.

(51) Int. Cl. H01L 27/16

(52) U.S. Cl. CPC H01L 27/16
USPC 257/467; 136/207

(57) ABSTRACT

Systems and methods for harvesting dissipated heat from integrated circuits (ICs) in electronic devices into electrical energy for providing power for the electronic devices are disclosed. In one embodiment, energy transferred from one or more ICs in the form of dissipated heat is harvested to convert at least a portion of this dissipated heat into electricity. This power can be used to provide power to the ICs to reduce overall power consumption by the electronic device. The harvested dissipated heat can be supplied to ICs in the electronic device to provide power to the ICs. Alternatively, or in addition, the harvested dissipated heat can be stored in an energy storage device to provide power to the ICs at a later time.

### PRIORITY APPLICATION

The present application claims priority to U.S. Provisional Patent Application Ser. No. 61/774,039, filed Mar. 7, 2013, entitled SYSTEMS AND METHODS FOR HARVESTING DISSIPATED HEAT FROM INTEGRATED CIRCUITS (IC) IN ELECTRONIC DEVICES INTO ELECTRICAL ENERGY FOR PROVIDING POWER FOR THE ELECTRONIC DEVICES, which is incorporated herein by reference in its entirety.

### BACKGROUND

I. Field of the Disclosure

The field of the present disclosure relates to heat management in electronic devices employing integrated circuits (ICs).

II. Background

Electronic devices are manufactured using integrated circuits (ICs). These electronic devices require a power source to provide power to the ICs for operation. A common power source for portable electronic devices is a battery, which provides a power source for operating ICs within the portable electronic devices. Reducing power consumption in ICs, especially ICs in portable electronic devices, has been an area of concentration in designing ICs. Reduced power consumption results in longer battery life. Reduced power consumption can also result in lower heat generation that needs to be dissipated. Many electronic devices include various means to dissipate heat even if the devices have reduced power consumption demands.

One technique to reduce IC power consumption is to reduce the amount of time that active components (e.g., gates, registers, flip-flops) are exercised. Clock gating and power collapsing are two methods to reduce active component usage. In recent years, near threshold operation techniques have also been employed to reduce power consumption. Near threshold operation involves lowering the supply voltage to voltage values close to the threshold operational voltage of the gates to reduce consumed power. However, in any of these IC power reduction techniques, a certain amount of power inefficiency will be generated in the form of heat.

While power conservation techniques are actively being explored, there still remains a need for better power management, particularly in portable electronic devices where there is a strong need to maximize an amount of time available between battery recharging events.

### SUMMARY OF THE DISCLOSURE

Embodiments disclosed herein include systems and methods for harvesting dissipated heat from integrated circuits (ICs) in electronic devices into electrical energy for providing power. Energy transferred from one or more ICs in the form of dissipated heat is harvested to convert at least a portion of this dissipated heat into electricity. This power can be used to provide power to the ICs to reduce overall power consumption by the electronic device. The harvested dissipated heat can be supplied to ICs in the electronic device to provide power to the ICs. Alternatively, or in addition, the harvested dissipated heat can be stored in an energy storage device to provide power to the ICs at a later time. While it is expected that multiple ICs may be used concurrently the concepts remain applicable to a single IC.

In this regard, in an exemplary embodiment, a semiconductor package is disclosed. The semiconductor package comprises a semiconductor die disposed on a substrate. The semiconductor package further comprises a thermo-electric material distinct from and thermally coupled to at least a portion of the semiconductor die.

In another exemplary embodiment, an IC is disclosed. The IC comprises a semiconductor package. The semiconductor package comprises a semiconductor die disposed on a substrate and a thermo-electric material distinct from and thermally coupled to at least a portion of the semiconductor die, wherein the thermo-electrical material is configured to convert dissipated heat from the semiconductor die into electrical energy. The IC also comprises a voltage conditioning circuit configured to receive the converted electrical energy. The voltage conditioning circuit is also configured to condition the converted electrical energy to provide power to the IC.

In another exemplary embodiment, a printed circuit board (PCB) is disclosed. The PCB comprises a substrate. The PCB also comprises at least one thermo-electric material portion embedded in a portion of the substrate.

In another exemplary embodiment, a semiconductor package is disclosed. The semiconductor package comprises a semiconductor die disposed on a substrate. The semiconductor package also comprises a means for converting thermal energy to electrical energy distinct from and thermally coupled to at least a portion of the semiconductor die.

### BRIEF DESCRIPTION OF THE FIGURES

FIG. 1 illustrates a graph of Carnot efficiency curves vs. temperature for a heat engine;

FIG. 2 illustrates a graph of efficiency curves for thermoelectric materials Bismuth Telluride and Copper-Selenium vs. temperature;

FIG. 3 illustrates one embodiment of the proposed integrated circuit (IC) packaging using thermoelectric material; for this embodiment the entire packaging is made of thermoelectric material;

FIG. 4 illustrates one embodiment of the proposed IC packaging using thermoelectric material; for this embodiment the thermoelectric material is used only over the die;

FIG. 5 illustrates one embodiment of the proposed embedding of thermoelectric material in the printed circuit board (PCB) underneath the IC of interest for energy harvesting; and

FIG. 6 is a block diagram of an exemplary processor-based system that can include an IC of FIGS. 3-5.

### DETAILED DESCRIPTION

With reference now to the drawing figures, several exemplary embodiments of the present disclosure are described. The word “exemplary” is used herein to mean “serving as an example, instance, or illustration.” Any embodiment described herein as “exemplary” is not necessarily to be construed as preferred or advantageous over other embodiments.

Embodiments disclosed herein include systems and methods for harvesting dissipated heat from integrated circuits (ICs) in electronic devices and converting this harvested heat into electrical energy for providing power back to the ICs. Energy transferred from one or more ICs in the form of dissipated heat is harvested to convert at least a portion of this dissipated heat into electricity. This power can be used to provide power to the ICs to reduce overall power consumption by the electronic device. The harvested dissipated heat can be supplied to ICs in the electronic device to provide power to the ICs. Alternatively, or in addition, the harvested dissipated heat can be stored in an energy storage device to provide power to the ICs at a later time.

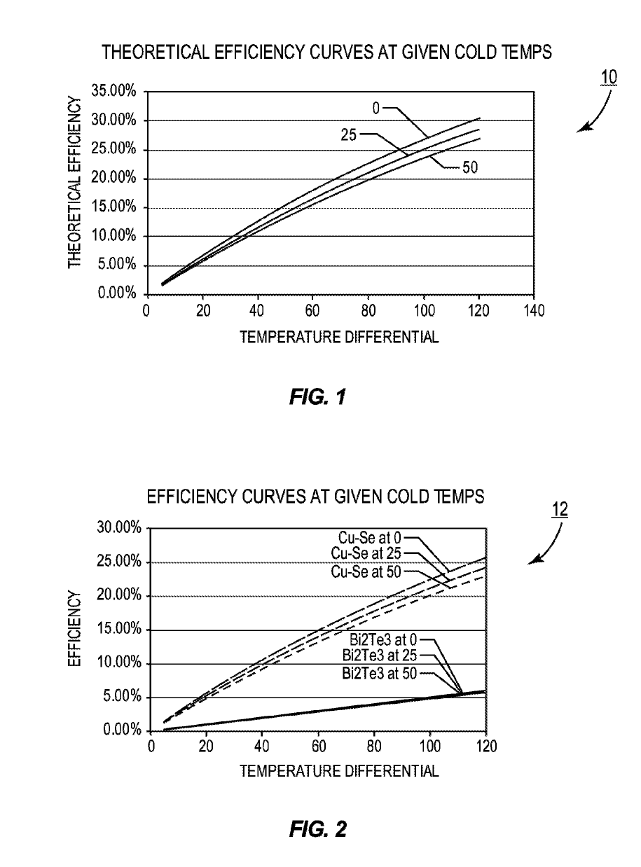

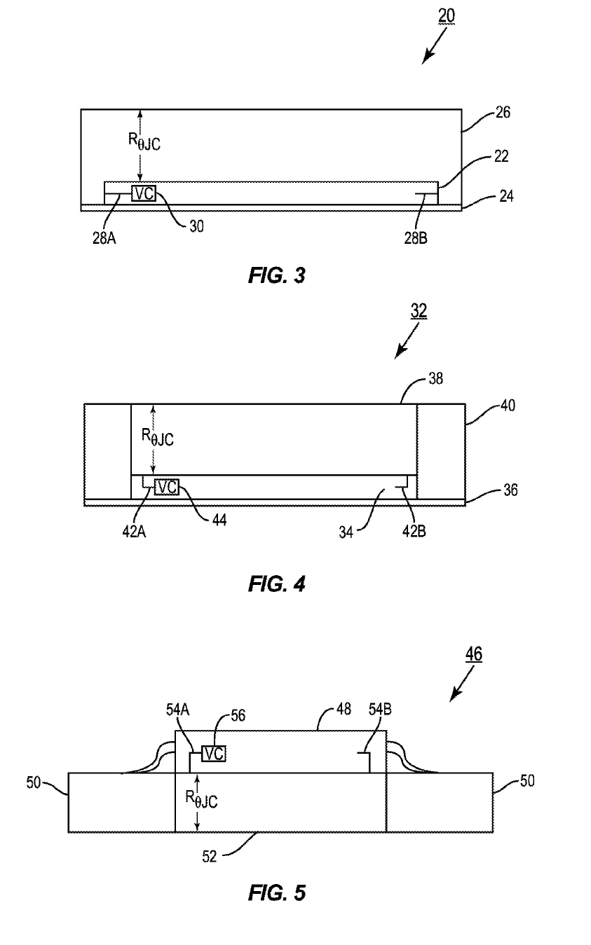

Before addressing the particulars of the heat harvesting techniques of the present disclosure, a discussion of the physics associated with thermoelectric behavior are provided with reference to the graphs of FIGS. 1 and 2 and accompanying equations. The discussion of embodiments of the present disclosure begins below with reference to FIG. 3.

Harvesting dissipated heat from ICs into electrical energy for providing power and converting this harvested heat back into electrical energy reduces the effective power consumption of the ICs of the electronic device. As noted above, reduction in the effective power consumption may extend battery life for mobile devices. Also, converting dissipated heat from the ICs into electrical energy can result in an equivalent reduction of heat released into the space within the electronic device. This heat release reduction can result in a lower substrate temperature of the ICs thereby possibly allowing the ICs to operate at higher frequencies without the IC substrate(s) temperature crossing over an undesired or dangerous temperature threshold. Such increases in frequency may allow faster operation.

The harvested heat converted into electrical energy can result in an effective reduction of IC power consumption by an amount equal to the efficiency of the energy harvesting system. For example, if the energy harvesting efficiency of the energy harvesting system is five percent (5%) (e.g., generating 5 mW of power from 100 mW of dissipated heat), the overall power consumption of the IC will be reduced by five percent (5%). A bit of additional background is provided.

Heat Engines, Thermoelectric Generators and Efficiencies

Energy harvesting is the process by which external sources of energy are converted to other forms of energy to be stored or used by electronic devices. Such external sources consist of, but are not limited to solar, wind, heat, kinetic or ambient radio frequency (RF) energy. In all such cases, a mechanism is employed by which part of the energy is absorbed and converted into either electrical or chemically stored energy.

In the case of heat, the material used to absorb and convert heat energy (temperature gradients) directly into electricity is called thermoelectric generator (or thermo-generator) and the direct conversion of temperature difference into electric voltage is called thermoelectric effect. Thermoelectric effect, in reality, encompasses three different effects: The Seebeck effect, Peltier effect and Thomson effect collectively referred to as Seebeck-Peltier Thomson effect.

The maximum efficiency (ηₘₐₓ) of any heat engine, and therefore thermo-generators, is given by the Carnot's theorem, and is limited to:

$${η}_{max} = 1 - \frac{{T}_{C}}{{T}_{H}} = 1 - \frac{{T}_{c}}{{T}_{c} + Δ T} \qquad Eq . 1$$

where T_{C} and T_{H} are the cold and hot temperatures respectively given in units of Kelvin. As can be seen from Eq. 1, as the hot temperature increases the maximum theoretical efficiency approaches 1 or 100%. The maximum efficiency is plotted in graph 10 of FIG. 1 for a range of cold temperatures and temperature differentials (ΔT) of 5 to 120° C. As can be seen from this plot, at a temperature differential of 60° C. over a cold temperate of 25° C. the maximum theoretical efficiency is 16.75%.

The efficiency of thermoelectric devices, however, contains additional terms as shown below:

$$η = ( 1 - \frac{{T}_{C}}{{T}_{H}} ) \frac{\sqrt{1 + Z T} - 1}{\sqrt{1 + Z T} + \frac{{T}_{c}}{{T}_{H}}} \\ where , \\ Z = \frac{{( {S}_{p} - {S}_{n} )}^{2}}{{[ \sqrt{{ρ}_{n} {κ}_{n}} + \sqrt{{ρ}_{p} {κ}_{p}} ]}^{2}} \qquad Eq . 2$$

is the figure of merit, and where ρ is the electrical resistivity, κ is the thermal conductivity, T̅ is the average temperature between hot and cold surfaces, S is the Seebeck coefficient and n and p denote n- and p-type semiconducting material. Much of the research in thermoelectric material is focused on reducing ρ and κ while increasing S to achieve a higher figure of merit Z.

Currently, the most efficient thermoelectric materials are formed as alloys of Bismuth Telluride (Bi₂Te₃.) The average thermoelectric figure of merit Z of crystals of Bismuth Telluride is between 2.8×10⁻³ and 3×10⁻³ l/K at 300K. Using this figure of merit for Z in Eq. 2 and plotting the efficiency η for various cold temperatures and temperature differentials (ΔT) as before, the family of curves shown in graph 12 of FIG. 2 is obtained. As before, examining the thermoelectric efficiency at a temperature differential of 60° C. over a cold temperate of 25° C., a value of 3.06% is obtained. Another observation to be made from these curves is that the variation in efficiencies due to differences in the cold temperature is very small and limited to less than 0.25%.

Advances in material sciences are giving rise to thermoelectric materials with better efficiencies. Carbon nanotube. Gallium Manganese Arsenide (with thermo-spin effects) and a copper-selenium liquid-like crystal are a few examples of the latest research in finding more efficient thermoelectric material. Copper-selenium material, for example, has been found to have a thermoelectric figure of merit of ˜0.4 at 300K. The family of efficiency curves for a figure of merit of 0.4 has also been plotted in graph 12 of FIG. 2. As seen, with this figure of merit, the efficiencies are very close to the theoretical ones for a general thermal engine given in FIG. 1. Thus, numerous materials exist which are amenable to use as a thermoelectric material in an IC if they meet the other engineering requirements for the product.

### The Effect of Thermal Resistance

Against the theoretical backdrop of the Carnot curves of FIGS. 1 and 2,

FIG. 3 shows an exemplary embodiment of an IC 20 having a thermoelectric material associated therewith to harvest heat energy generated by the active components within the IC 20 for conversion back to electrical energy for subsequent use. The IC 20 includes a die 22 having the active components formed therein. The die 22 is positioned on a substrate 24. A thermoelectric casing 26 abuts and surrounds the die 22 on all sides other than the side of the die 22 bonded to the substrate 24. Note that the thermoelectric material of the thermoelectric casing 26 is distinct from the die 22, but is directly thermally coupled to at least a portion of the die 22. In this manner, the heat generated by the active components of the die 22 is directly transferred to the thermoelectric material within the thermoelectric casing 26. As noted above, the thermoelectric casing 26 may be from a number of different materials. In an exemplary embodiment, the thermoelectric casing 26 is made from a carbon nanotube, Gallium Manganese Arsenide (with thermo-spin effects), a copper-selenium liquid-like crystal, or bismuth telluride material.

With continued reference to FIG. 3, electrical leads 28A, 28B (collectively or generically electrical leads 28) are coupled from the thermoelectric material of the thermoelectric casing 26 and are further coupled to voltage conditioning (VC) circuitry 30. The VC circuitry 30 may contain elements that may transform the harvested energy to a format that is usable by other elements within the die 22 or a format that is storable by a capacitor or a rechargeable battery. For example, the current and/or voltage levels produced by the thermoelectric material may be manipulated so as to provide a desired current and/or voltage levels for a particular active component within the die 22. Note that while the thermoelectric material may convert heat to electricity for use by the die 22, the thermoelectric material may also be configured to dissipate heat in response to received electrical energy and therefore be used as a cooling means for the die 22. Also note that as used herein, the thermoelectric material may also be referred to a means for converting thermal energy to electric energy.

With continued reference to FIG. 3, another parameter of interest is the thermal resistance (1/κ m° C./W) of the thermoelectric material within the thermoelectric casing 26. The thermal differential across the thermoelectric casing 26 is measured as the product of the power dissipated by the IC and the absolute thermal resistance (R_{θJC}) of the casing given by:

$${R}_{θ J C} = \frac{x}{A κ} \qquad Eq . 3$$

where x is the height of the material and A the cross sectional area. Therefore, the thermal differential ΔT is given by:

ΔT=Q(1−η)×R_{θJC} Eq.4

where Q is the power dissipated by the IC, and η denotes the fraction of the power that is being harvested. As it can be seen from Eq. 4, the efficiency parameter η itself is a function of ΔT. Therefore, final ΔT is determined by substituting for η and solving for ΔT.

$$Δ T = Q ( 1 - ( \frac{Δ T}{{T}_{v} + Δ T} ) \frac{\sqrt{1 + Z \frac{2 {T}_{c} + Δ T}{2}} - 1}{\sqrt{1 + Z \frac{2 {T}_{c} \vert Δ T}{2} + \frac{{T}_{c}}{{T}_{c} + Δ T}}} ) \times {R}_{θ J C} \qquad Eq . 5$$

Using Eq. 5, one option is to use iterative algorithms and determine the final value of ΔT. Alternatively, the simplifying assumption that 2T_{c}>>ΔT is used to find a closed form solution for ΔT with a good approximation for the range of ΔTs of interest. Making this assumption, Eq. 5 can be re-written as

$$Δ T \approx Q ( 1 - ( \frac{Δ T}{{T}_{c} + Δ T} ) \frac{\sqrt{1 + Z {T}_{c}} - 1}{\sqrt{1 + Z {T}_{c}} + \frac{{T}_{c}}{{T}_{c} + Δ T}} ) \times {R}_{θ J C} \qquad Eq . 6$$

Eq. 6 can then be written as a quadratic equation in terms of ΔT, where its positive root is the solution for ΔT.

$$Δ T \approx \frac{- b + \sqrt{{b}^{2} - 4 a c}}{2 a} \\ where \\ a = \sqrt{1 + Z {T}_{c}} \\ b = ( a + 1 ) {T}_{c} - Q {R}_{θ J C} \\ c = ( a + 1 ) {T}_{c} Q {R}_{θ J C} \qquad Eq . 7$$

It is worth noting that according to the efficiency curves in FIG. 1 and FIG. 2, the larger the temperature differential, the higher the efficiency. Consequently, it is better for the absolute thermal resistance of the thermoelectric casing 26 to be large enough to give rise to a higher temperature differential, and therefore, a higher efficiency. Increased thermal resistance of the thermoelectric casing 26 is achieved by reducing the cross sectional area of the casing 26, increasing the height, or using a material with smaller thermal conductivity κ. The absolute thermal resistance, at the same time, needs to be small enough to maintain a safe operating temperature for the die 22, which is typically a silicon material. Thus, to achieve a desired heat harvesting device, an appropriate material is selected and positioned so as to maximize its heat harvesting opportunities.

The junction temperature T of the die 22 is determined by the addition of the temperature difference in the thermoelectric casing 26 plus the ambient temperature (which is the temperature at which the cold side of the thermoelectric material or the thermoelectric casing 26 is maintained). Therefore, the junction temperature Tⱼ of the die 22 is given by:

T_{J}=T_{AMB}+ΔT Eq. 8

The thermal conductivity of Bismuth Telluride is reported to be 1.20 (W/(° C. m)). Therefore, as an exemplary use case, for a typical cell phone power amplifier (PA) with package dimensions of 3 mm×3 mm×1 mm, the absolute thermal resistance of the casing made of Bismuth Telluride material would be

$${R}_{θ J C} = \frac{x}{A κ} = \frac{{10}^{- 5} m}{9 \times {10}^{- 6} {m}^{2} \times 1.2 \frac{W}{m ° C .}} = 92.59 ° C . / W$$

The power dissipated by the PA, on the other hand, at its maximum output power (and max efficiency of ˜40%) would result in a dissipated power of

$$\begin{matrix}max ( {P}_{out} ) = \sim 28 dBm \\ Eff {\vert}_{max ( {P}_{out} )} = 40 \%\end{matrix} \} ⇒ Q = \frac{3}{2} {10}^{22} = 0.95 W$$

and a temperature differential of

ΔT≈84° C.

and, assuming an ambient temperature of 25° C., a junction temperature of

T_{J}=T_{AMB}+ΔT=10° C.

The thermal efficiency of the thermoelectric casing 26 of such device, on the other hand, would be ˜4.22%. If the harvested energy is then put through VC circuitry 30 with an exemplary efficiency of 90%, the overall efficiency for the harvested electrical energy would be ˜3.8% of the dissipated power. In other words, the overall wasted power by the PA would be reduced by ˜3.8% resulting in an overall increase in the efficiency of the PA.

A greater benefit is realized when thermoelectric material with higher efficiency and lower thermal conductance (higher thermal resistance,) such as carbon nanotubes or copper-selenium is used. For example, if copper-selenium's reported figure of merit is accurate, and proceeding with the assumption that the absolute resistance remains the same (in reality, it is expected that copper-selenium has a lower thermal conductivity and, therefore, a higher absolute resistance for the same package size,) the thermoelectric efficiency number for the PA example above would be at ˜17%. Assuming the same 90% efficiency for the VC circuitry, this would reduce the overall power consumption of the PA by ˜10%, effectively increasing the PA efficiency to ˜45%.

It is also worth noting that for the example above with copper-selenium as the thermoelectric material, the temperature differential ΔT will be 71° C. instead of 84° C. for Bismuth Telluride. The decrease in temperature differential is, of course, directly related to the fact that the more efficient copper-selenium material harvests a bigger fraction of the heat energy, reducing the amount of energy wasted in the form of heat. Therefore, with more efficient material, not only is more energy extracted from the wasted heat energy, the chips remain cooler.

Data modem chips can serve as another example to better understand the power saving potentials of this disclosure. Currently, a typical data modem chip package is 8 mm×8 mm×1 mm. Assuming a power profile that dissipates ˜1.5 W of power and a thermoelectric package with a conservative thermal conductivity of 1.20 (W/(° C. m)) (that of Bismuth Telluride,) the temperature differential across the package would be ˜18° C. Assuming the thermoelectric package is made of copper-selenium, however, with a figure of merit of 0.4 and a 90% efficiency for the VC circuitry, the overall energy harvesting efficiency would be at ˜5%; effectively, reducing the power consumption of the data modem chip by the same amount.

It is also worth noting that as stated before, the absolute thermal resistivity of the thermoelectric material of the thermoelectric casing 26 can be increased by reducing its cross sectional area as deduced from Eq. 2.

In this regard, FIG. 4 illustrates an exemplary IC 32 such as a modem or central processing unit (CPU) where the packaging is larger than the die itself. The IC 32 includes a die 34 positioned on a substrate 36. Such an IC is normally encased in a plastic material. In this exemplary embodiment, the normal plastic casing is at least partially replaced by thermoelectric material forming a thermoelectric casing 38, which together with remaining plastic casing 40 encapsulates the die 34. As with the previous embodiment, the thermoelectric material of the thermoelectric casing 38 abuts and is directly thermally coupled to the die 34 such that the most efficient transfer of heat from the die 34 to the thermoelectric material is effectuated.

With continued reference to FIG. 4, the die 34 may include electrical leads 42A, 42B (collectively or generically electrical leads 42) which electrically couple the thermoelectric material of the thermoelectric casing 38 to VC circuitry 44. As discussed above, the VC circuitry 44 may condition the energy by changing the voltage level or current level for immediate use by active components in the die 34 or to be stored by a capacitor or a rechargeable battery.

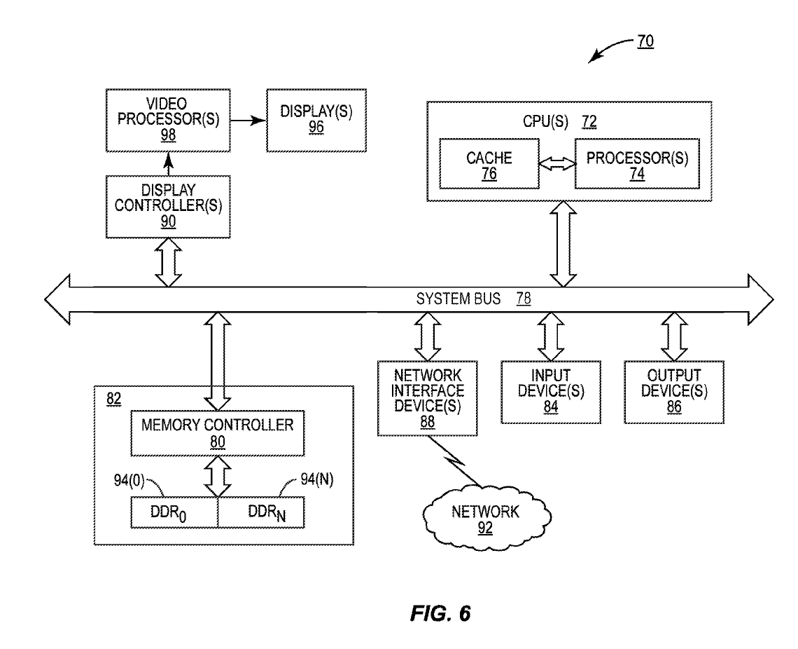

Another exemplary embodiment is illustrated in FIG. 5. The embodiment of FIG. 5 may be appropriate for use when the IC is designed to conduct most of the heat into the printed circuit board (PCB). An exemplary IC that operates in this fashion is a PA. In this regard, IC package 46 includes an IC 48 positioned on a PCB 50. PCB 50 has a thermoelectric material 52 embedded therein. The thermoelectric material 52 abuts and is directly thermally coupled to the IC 48. Electrical leads 54A, 54B (collectively or generically electrical leads 54) electrically couple the thermoelectric material 52 to VC circuitry 56, which is substantially similar to VC circuitry 44 (described above with reference to FIG. 4). This embodiment of the disclosure has the added advantage of increasing the thickness of the thermoelectric material 52, and therefore, increasing its absolute thermal resistance to where a larger thermal differential can be maintained across the thermoelectric material 52 resulting in higher efficiency. As another embodiment, the VC circuitry 56 may reside external to the heat producing IC 48.

As a final example, for the case of the modem chip above, if the absolute thermal resistance is increased (through reducing cross sectional area, increasing thickness or reducing the thermal conductivity) such that the temperature differential across the thermoelectric material reaches 95° C., the overall efficiency will increase to ˜20%.

The systems and methods for harvesting dissipated heat from ICs in electronic devices into electrical energy for providing power for the electronic devices according to embodiments disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

In this regard, FIG. 6 illustrates an example of a processor-based system 70 that can employ the ICs illustrated in FIGS. 3-5. In this example, the processor-based system 70 includes one or more CPUs 72, each including one or more processors 74. The CPU(s) 72 may have cache memory 76 coupled to the processor(s) 74 for rapid access to temporarily stored data. The CPU(s) 72 is coupled to a system bus 78 and can intercouple master devices and slave devices included in the processor-based system 70. As is well known, the CPU(s) 72 communicates with these other devices by exchanging address, control, and data information over the system bus 78. For example, the CPU(s) 72 can communicate bus transaction requests to the memory controller 80.

Other master and slave devices can be connected to the system bus 78. As illustrated in FIG. 6, these devices can include a memory system 82, one or more input devices 84, one or more output devices 86, one or more network interface devices 88, and one or more display controllers 90, as examples. The input device(s) 84 can include any type of input device, including but not limited to input keys, switches, voice processors, etc. The output device(s) 86 can include any type of output device, including but not limited to audio, video, other visual indicators, etc. The network interface device(s) 88 can be any devices configured to allow exchange of data to and from a network 92. The network 92 can be any type of network, including but not limited to a wired or wireless network, private or public network, a local area network (LAN), a wide local area network (WLAN), and the Internet. The network interface device(s) 88 can be configured to support any type of communication protocol desired. The memory system 82 can include one or more memory units 94(0-N).

The CPU(s) 72 may also be configured to access the display controller(s) 90 over the system bus 78 to control information sent to one or more displays 96. The display controller(s) 90 sends information to the display(s) 96 to be displayed via one or more video processors 98, which process the information to be displayed into a format suitable for the display(s) 96. The display(s) 96 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the embodiments disclosed herein may be implemented as electronic hardware, instructions stored in memory or in another computer-readable medium and executed by a processor or other processing device, or combinations of both. The arbiters, master devices, and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the embodiments disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The embodiments disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. A semiconductor package, comprising:
a semiconductor die disposed on a substrate; and
thermo-electric material distinct from and thermally coupled to at least a portion of the semiconductor die.

2. The semiconductor package of claim 1, wherein the thermo-electrical material is configured to convert dissipated heat from the semiconductor die into electrical energy.

3. The semiconductor package of claim 1, wherein the thermo-electrical material is configured to dissipate heat from the semiconductor die in response to received electrical energy.

4. The semiconductor package of claim 1, wherein the thermo-electric material forms a portion of the semiconductor package.

5. The semiconductor package of claim 1 forming an integrated circuit (IC).

6. The semiconductor package of claim 1, wherein the thermo-electric material forms a casing around the semiconductor die.

7. The semiconductor package of claim 6, wherein the thermo-electric material is external to but directly abutting the semiconductor die.

8. The semiconductor package of claim 1, wherein the thermo-electric material comprises a bismuth telluride material.

9. The semiconductor package of claim 1, wherein the thermo-electric material is selected from the group consisting of: carbon nanotubes, gallium manganese arsenide, and copper-selenium.

10. The semiconductor package of claim 1, further comprising a device selected from the group consisting of a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player, into which the semiconductor package is integrated.

11. An integrated circuit (IC), comprising:
a semiconductor package, comprising:
a semiconductor die disposed on a substrate; and
thermo-electric material distinct from and thermally coupled to at least a portion of the semiconductor die;
wherein the thermo-electrical material is configured to convert dissipated heat from the semiconductor die into electrical energy; and
a voltage conditioning (VC) circuit configured to:
receive the converted electrical energy; and
condition the converted electrical energy to provide power to the IC.

12. The IC of claim 11, wherein the VC circuit is configured to condition the converted electrical energy to provide power to the IC by storing the converted electrical energy in an energy storage device coupled to the IC and configured to provide power to the IC.

13. The IC of claim 11, wherein the VC circuit is configured to condition the converted electrical energy to provide power to the IC by directing the converted electrical energy to the IC to provide at least a portion of the power to operate the IC.

14. The IC of claim 11, wherein the thermo-electric material forms a casing around the semi-conductor die.

15. The IC of claim 14, wherein the casing further comprises a plastic edge portion coupled to the substrate.

16. The IC of claim 14, wherein the casing abuts the semiconductor die.

17-18. (canceled)

19. A semiconductor package, comprising:
a semiconductor die disposed on a substrate; and
means for converting thermal energy to electric energy distinct from and thermally coupled to at least a portion of the semiconductor die.

20. The semiconductor package of claim 19, wherein the means for converting thermal energy comprises a casing coupled to the substrate and surrounding the semiconductor die while abutting the semiconductor die and configured to harvest thermal energy generated within the semiconductor die and dissipate thermal energy generated within the semiconductor die.
